(19) United States
(12) Patent Application Publication
(10) Pub. No.: US 2025/0234484 A1
(43) Pub. Date: Jul. 17, 2025

(54) LEAK PREVENTION AND DETECTION IN LIQUID-COOLED PACKAGES

(71) Applicant: LENOVO ENTERPRISE SOLUTIONS (SINGAPORE) PTE. LTD., SINGAPORE (SG)

(72) Inventor: TIANYI GAO, GREENSBORO, NC (US)

(21) Appl. No.: 18/412,180

(22) Filed: Jan. 12, 2024

(51) Int. Cl. H05K 7/20

(52) U.S. Cl. CPC H05K 7/20272; H05K 7/20327; H05K 7/20336

(57) ABSTRACT

Systems and apparatus for adjusting power caps for leak prevention and detection in liquid-cooled packages include a circuit board and a cooling package coupled to, and configured to cool, the circuit board, where the cooling package includes: a package top plate and a package base coupled to the package top plate, where the package base includes: a cooling chamber comprising one or more cooling components, and a leak channel configured to catch and store liquid that has leaked out of the cooling chamber.

### BACKGROUND

The present disclosure relates to methods, apparatus, and systems for leak prevention and detection in liquid-cooled packages.

### SUMMARY

Methods, systems, and apparatus for leak prevention and detection in liquid-cooled packages according to various embodiments are disclosed in this specification. In accordance with one aspect of the present disclosure, a system for leak prevention and detection in liquid-cooled packages includes a circuit board and a cooling package coupled to, and configured to cool, the circuit board, where the cooling package includes: a package top plate and a package base coupled to the package top plate, where the package base includes: a cooling chamber comprising one or more cooling components, and a leak channel configured to catch and store liquid that has leaked out of the cooling chamber.

In accordance with another aspect of the present disclosure, leak prevention and detection in liquid-cooled packages may include a system including: a processor, and a keyboard having one or more backlit keyboard keys, where at least one of the one or more backlit keyboard keys includes: a socket comprising a light, and a keycap coupled to the socket, where the keycap includes: a first color filter corresponding to a first character, where the first character is displayed on the keycap based on a color of the light matching the first color filter, and a second color filter corresponding to a second character, where the second character is displayed on the keycap based on the color of the light matching the second color filter.

The foregoing and other objects, features and advantages of the disclosure will be apparent from the following more particular descriptions of exemplary embodiments of the disclosure as illustrated in the accompanying drawings wherein like reference numbers generally represent like parts of exemplary embodiments of the disclosure.

### BRIEF DESCRIPTION OF THE DRAWINGS

FIG. 1 shows an example block diagram of a system for leak prevention and detection in liquid-cooled packages in accordance with embodiments of the present disclosure.

FIG. 2 shows an example block diagram of another system for leak prevention and detection in liquid-cooled packages in accordance with embodiments of the present disclosure.

FIG. 3 shows an example block diagram of another system for leak prevention and detection in liquid-cooled packages in accordance with embodiments of the present disclosure.

FIG. 4 shows an example block diagram of another system for leak prevention and detection in liquid-cooled packages in accordance with embodiments of the present disclosure.

FIG. 5 is a flowchart of an example method of manufacturing liquid-cooled packages configured for leak prevention and detection according to some embodiments of the present disclosure.

### DETAILED DESCRIPTION

Liquid cooling packages may be mounted to circuit boards or other computing components to help regulate their temperature. However, if these liquid cooling packages leak, they can damage surrounding components and cause other various issues. Further, it can be hard to determine the precise source of the leak, and the leak is not usually detected until after the resulting damage has occurred. It would be beneficial to have a liquid cooling package that allows for early leak detection and even leak prevention.

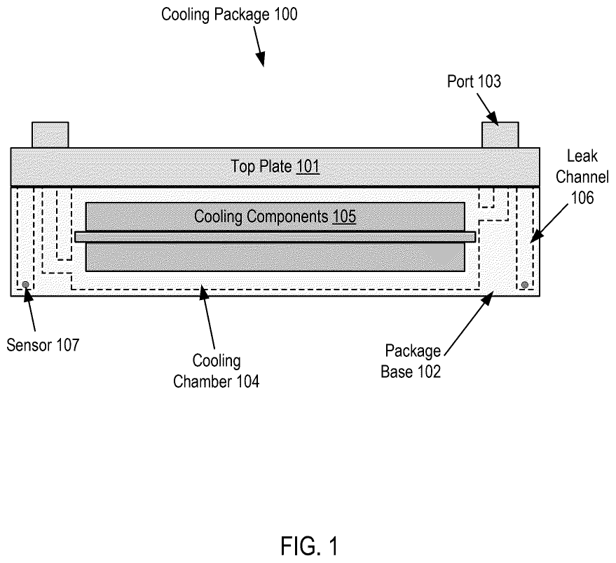

Exemplary methods, systems, and products for leak prevention and detection in liquid-cooled packages in accordance with the present disclosure are described with reference to the accompanying drawings, beginning with FIG. 1. FIG. 1 sets forth an example block diagram of a system for leak prevention and detection in liquid-cooled packages in accordance with embodiments of the present disclosure. FIG. 1 shows a cooling package 100 that includes a package top plate (top plate 101) and a package base 102 coupled to the top plate. The cooling package 100 is configured to couple to a circuit board or other computing component or device for cooling and temperature regulation.

The example top plate 101 of FIG. 1 includes multiple ports (such as port 103) configured to circulate liquid through the cooling package 100. The example top plate of FIG. 1 is shown with two ports. In another embodiment, the top plate may include more than two ports. The example ports are configured to couple to cooling lines that circulate liquid in and out of the cooling package 100.

The example package base 102 of FIG. 1 is coupled to the underside of the top plate 101 is configured with cooling components that help to cool the liquid circulating through the cooling package 100. The package base 102 of FIG. 1 includes a cooling chamber 104 and a leak channel 106. The cooling chamber 104 is configured to house one or more cooling components (such as cooling components 105). The leak channel 106 is configured to catch and store any liquid that leaks out of the cooling chamber, so that the liquid cannot make it outside of the cooling package 100 and damage any surrounding components. The leak channel 106 includes one or more sensors (such as sensor 107). Sensor 107 is configured to detect any liquid that leaks out of the cooling chamber and into the leak channel.

In one example, liquid from within the cooling chamber 104 of FIG. 1 may begin to leak out from between the top plate 101 and the package base 102. In such an example, the leak channel 106 is configured to catch the leaking liquid before it is able to leak out of the cooling package 100. Continuing with the example, the sensor 107 in the leak channel 106 is configured to detect the liquid that is leaking out of the cooling chamber and caught by the leak channel. In such an example, a notification or may be sent to an administrator or other personnel indicating the presence of the leak, along with any location information associated with the leak. Information regarding the leak may be stored in memory (such as memory remote to the cooling package). Accordingly, in such an example, the cooling package is configured to prevent a leak from occurring by catching the leaking liquid prior to it leaving the cooling package, and also detect the leak before it has a chance to damage any surrounding components.

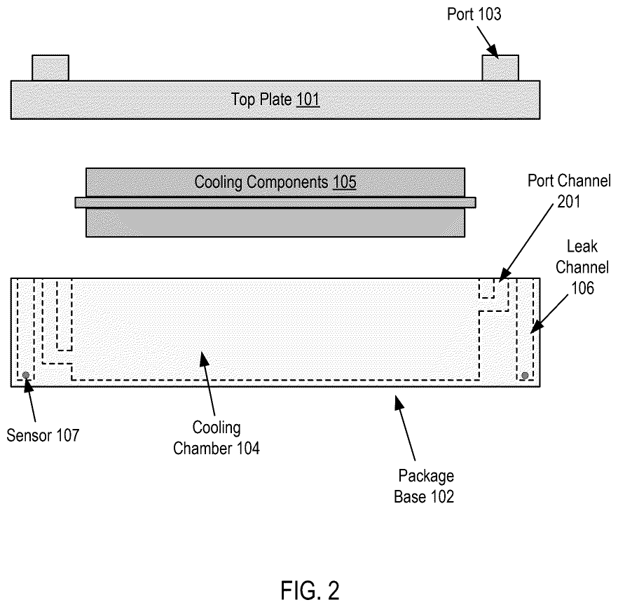

For further explanation, FIG. 2 sets forth an example block diagram of another system for leak prevention and detection in liquid-cooled packages in accordance with embodiments of the present disclosure. The example system of FIG. 2 shows an expanded view of a cooling package (such as the cooling package 100 of FIG. 1) to show the various parts of the cooling package. The cooling chamber 104 is configured as an open space or cavity within the package base configured to hold one or more cooling components (such as cooling components 105).

The example package base 102 of FIG. 2 also includes port channel 201, which is configured to circulate liquid between the cooling chamber 104 and the port 103. In one embodiment, the package base includes a port channel corresponding to each port included within the top plate 101. The leak channel 106 is shown in FIG. 2 as being positioned near the edges of the package base 102. In one embodiment, the leak channel 106 is configured as a single channel positioned around the perimeter of the package base 102. In such an embodiment, any liquid that leaks out of the cooling chamber 104 or port channel 201 towards the edge of the cooling package (such as between the top plate and the package base) will be caught by the leak channel. That is, rather than leaking liquid passing to the outside of the cooling package, the leaking liquid will instead be forced into the leak channel 106. In one embodiment, for leaking liquid to leak outside of the cooling package, the liquid would have to first fill up the leak channel 106. In such an embodiment, a user, notified by the sensor 107 of the detected leak, will have a sufficient amount of time to correct the leak prior to any liquid leaking out of the cooling package and damaging any surrounding components.

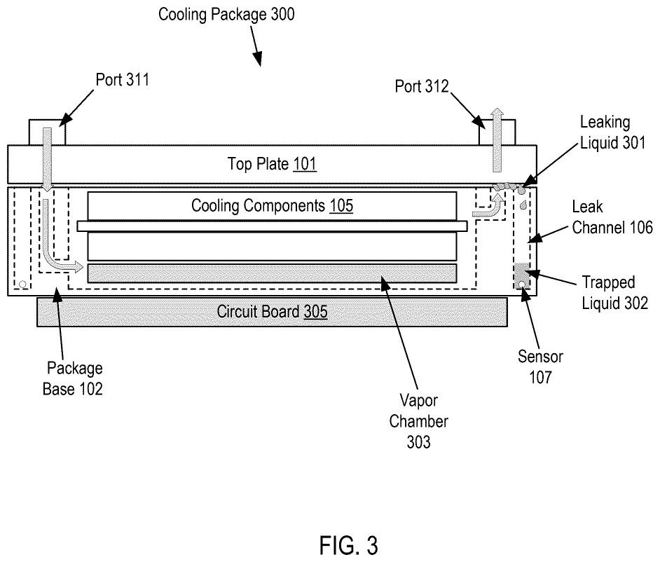

For further explanation, FIG. 3 sets forth an example block diagram of another system for leak prevention and detection in liquid-cooled packages in accordance with embodiments of the present disclosure. The example system of FIG. 2 shows another cooling package 300 configured for leak prevention and detection. FIG. 3 includes shaded arrows depicting the direction of flow for the liquid being circulated through the cooling package. Specifically, the cooling package 300 of FIG. 3 shows liquid being moved into the cooling package from port 311. In such an embodiment, port 311 is coupled to liquid tubing or lines (not shown in FIG. 3). The liquid from port 311 is shown in FIG. 3 as moving through the cooling chamber of the package base (from left to right) and eventually circulating out of the cooling package through port 312.

The example cooling package 300 of FIG. 3 also depicts liquid leaking out of the port channel corresponding with port 312. Specifically, FIG. 3 shows leaking liquid 301 seeping out of the port channel and along the interface between the top plate 101 and the package base 102. In the cooling package 300 of FIG. 3, the leak channel 106 prevents the leaking liquid 301 from making it outside of the cooling package 300 by catching the leaking liquid and storing it as trapped liquid 302 within the leak channel 106. In the example of FIG. 3, the sensor 107 detects the trapped liquid 302 within the leak channel 106 and sends, via a controller, a signal identifying the detection of the liquid that has leaked out of the cooling chamber. In such an embodiment, the signal may be in the form of a notification to a user, notifying the user of the detected leak, along with any corresponding information (such as the specific cooling package leaking, any component coupled to the cooling package, surrounding components, the time of the detected leak, the amount of time left before the leak begins affecting other components, and the like).

The example cooling package 300 of FIG. 3 also includes a vapor chamber 303 within the cooling chamber. The vapor chamber 303 may be included with the one or more cooling components 105 positioned in the cooling chamber of the package base 102. In other embodiments, any other cooling component may be positioned within the cooling chamber.

The example cooling package 300 of FIG. 3 also includes a circuit board 305 coupled to the cooling package 300 for cooling. In the example of FIG. 3, the circuit board 305 is coupled to the bottom surface of the package base 102, where the cooling package is configured to cool the bottom surface of the package base, and thereby cool the circuit board, via the cooling components 105. In other embodiments, the cooling package may be coupled to one or more other computing components. Not shown in FIG. 3, the cooling package may also include a sensor positioned between the top plate and the package base. For example, the cooling package, in addition to the sensor included within the leak channel, may also include one or more sensors along the interface between the top plate and the package base. In such an embodiment, the additional sensor would allow for the detection of liquid that has leaked out of the package base but has not yet reached the leak channel. In another example, one or more sensors could be positioned along the interface between the top plate and the package base outside of the leak channel, near the edge of the cooling package. In such an example, such a sensor is configured to detect liquid that has leaked out of the leak channel towards the outside of the cooling package (such as if the leak channel were to fill with liquid). Such a sensor allows for additional information by a user (through a second notification sent from the added sensor).

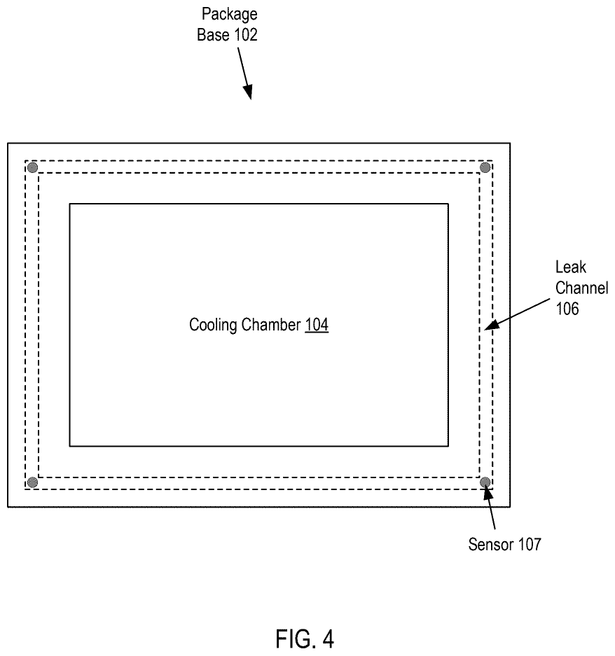

For further explanation, FIG. 4 sets forth an example block diagram of another system for leak prevention and detection in liquid-cooled packages in accordance with embodiments of the present disclosure. The example system of FIG. 2 includes a top view of the package base 102 for further explanation. The package base 102 of FIG. 4 includes a cooling chamber 104 positioned in the center of the package base, and a leak channel 106 positioned around the perimeter of the package base 102. Although not depicted in FIG. 4, any port channels (such as those shown in FIG. 2) included within the package base 102 are positioned between the cooling chamber 104 and the leak channel 106. In the example of FIG. 4, any liquid that leaks out of the cooling chamber 104 or port channel towards the edge of the cooling package will be trapped and stored by the leak channel.

The example of FIG. 4 also includes multiple sensors (such as sensor 107) positioned within the leak channel 106. Specifically, the example of FIG. 4 includes four sensors, with each sensor being positioned within the leak channel 106 at a different corner of the package base. In such an embodiment, even if the package base 102 is in a position that is not level, at least one sensor will always be able to detect any liquid that moves into the leak channel 106. In another embodiment, the leak channel may include only a single sensor. In another embodiment, the leak channel may include any number of sensors. In another embodiment, the four sensors may be positioned in the middle of each side of the package base, or some other position along each side of the leak channel. In one embodiment, the floor of the leak channel 106 is sloped to direct liquid towards one or more of the sensors included within the leak channel. In such an embodiment, the sloped floor of the leak channel helps to force any liquid reaching the leak channel towards one or more of the sensors included within it, independent of the position of the cooling package (such as when the package base is not level).

In the example of FIG. 4, the sensor 107 may be any type of sensor configured to detect the presence of liquid. In one embodiment, the sensor may be a standard fluid detector, having two wires. In such a sensor, when liquid contacts the sensor, the liquid completes the circuit between the two wires and causes the sensor to detect the liquid. In another embodiment, the sensor is a humidity sensor. In such an embodiment, the sensor is able to detect the presence of liquid within the leak channel without requiring direct contact between the sensor and the liquid. For example, in an embodiment where the cooling package is not level, and water leaks into the channel, the water may take a significant amount of time to reach the sensor. A humidity sensor present within the leak channel could be configured to detect the presence of liquid within the leak channel without having to wait for the liquid to reach and directly contact the sensor. In another embodiment, sloping the floor of the leak channel could further quicken the time required for leaked liquid to reach a sensor.

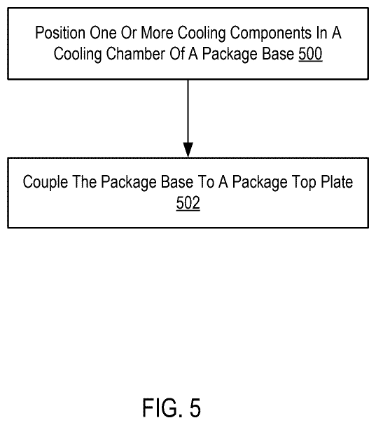

For further explanation, FIG. 5 sets forth a flowchart of an example method of manufacturing liquid-cooled packages configured for leak prevention and detection according to some embodiments of the present disclosure. The method of FIG. 5 includes positioning 500 one or more cooling components in a cooling chamber of a package base. In one embodiment, the package base includes the cooling chamber and a leak channel. In one embodiment, the leak channel is configured to catch and store liquid that has leaked out of the cooling chamber. The package base may be composed of a copper material (or any other thermally conductive material) and is configured to couple to a package top plate. The cooling chamber is configured to hold one or more cooling components and is configured to cool the liquid circulating in and out of the cooling chamber via the ports. The leak channel is configured to catch and store any liquid leaking out from the cooling chamber of the package base. The leak channel may be positioned around or near the perimeter of the top surface of the package base.

The method of FIG. 5 also includes coupling 502 the package base to a package top plate. Coupling 502 the package base to the package top plate may include using an adhesive to couple the package base to the package top plate. In one embodiment, the package top plate includes one or more ports, where the ports are each configured to couple to liquid tubing or lines. In another embodiment, mechanical fasteners may be used to couple the package base to the package top plate. In another embodiment, coupling 502 the package base to the package top plate may include using a gasket between the top plate and the package base. In such an embodiment, the gasket may be included outside the leak channel, to further prevent liquid from leaking out of the cooling package.

Not shown in FIG. 5, the method of FIG. 5 may further include positioning, in the leak channel of the package base, a sensor configured to detect liquid that has leaked into the leak channel from the cooling chamber. The sensor may be coupled to other computing components or circuitry, such as for propagating the signal from the sensor to another computing device or component. Also not included in FIG. 5, the leak channel may include a floor that slopes towards the one or more sensors positioned within the leak channel.

In view of the explanations set forth above, readers will recognize that the benefits of leak prevention and detection in liquid-cooled packages according to embodiments of the present disclosure include:
Decreasing the amount of time for detecting leaks from liquid-cooled packages, thereby reducing resulting damages and allowing for faster response to such a leak.
Decreasing the potential risk for leaks in liquid-cooled packages by preventing any leaks from leaving the cooling package.

The flowchart and block diagrams in the Figures illustrate the architecture, functionality, and operation of possible implementations of systems, methods, and apparatus according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Exemplary embodiments of the present disclosure are described largely in the context of a fully functional computer system for dynamic buffer selection in ethernet controllers. Readers of skill in the art will recognize, however, that the present disclosure also may be embodied in a computer program product disposed upon computer readable storage media for use with any suitable data processing system. Such computer readable storage media may be any storage medium for machine-readable information, including magnetic media, optical media, or other suitable media. Examples of such media include magnetic disks in hard drives or diskettes, compact disks for optical drives, magnetic tape, and others as will occur to those of skill in the art. Persons skilled in the art will immediately recognize that any computer system having suitable programming means will be capable of executing the steps of the method of the disclosure as embodied in a computer program product. Persons skilled in the art will also recognize that, although some of the exemplary embodiments described in this specification are oriented to software installed and executing on computer hardware, nevertheless, alternative embodiments implemented as firmware or as hardware are well within the scope of the present disclosure.

It will be understood from the foregoing description that modifications and changes may be made in various embodiments of the present disclosure without departing from its true spirit. The descriptions in this specification are for purposes of illustration only and are not to be construed in a limiting sense. The scope of the present disclosure is limited only by the language of the following claims.

What is claimed is:

1. An apparatus for leak prevention and detection in liquid-cooled packages, the apparatus comprising:
a package top plate; and
a package base coupled to the package top plate, wherein the package base includes:
a cooling chamber comprising one or more cooling components; and
a leak channel configured to catch and store liquid that has leaked out of the cooling chamber.

2. The apparatus of claim 1, wherein the leak channel includes a sensor configured to detect the liquid that has leaked into the leak channel from the cooling chamber.

3. The apparatus of claim 2, wherein the sensor comprises a humidity sensor.

4. The apparatus of claim 2, further comprising a controller configured to send a signal based on the sensor detecting the liquid in the leak channel.

5. The apparatus of claim 2, wherein a floor of the leak channel is sloped towards the sensor.

6. The apparatus of claim 1, wherein the leak channel is positioned around a perimeter of the package base.

7. The apparatus of claim 6, wherein the leak channel includes multiple sensors positioned within the leak channel around the package base.

8. The apparatus of claim 1, wherein at least one of the one or more cooling components includes a vapor chamber.

9. The apparatus of claim 1, wherein the package top plate includes one or more ports configured to circulate liquid through the package base.

10. A system for leak prevention and detection in liquid-cooled packages, the system comprising:
a circuit board; and
a cooling package coupled to the circuit board and configured to cool one or more components on the circuit board, wherein the cooling package includes:
a package top plate; and
a package base coupled to the package top plate, wherein the package base includes:
a cooling chamber comprising one or more cooling components; and
a leak channel configured to catch and store liquid that has leaked out of the cooling chamber.

11. The system of claim 10, wherein the leak channel includes a sensor configured to detect the liquid that has leaked into the leak channel from the cooling chamber.

12. The system of claim 11, wherein the cooling package comprises a controller configured to send a signal based on the sensor detecting the liquid in the leak channel.

13. The system of claim 11, wherein a floor of the leak channel is sloped towards the sensor.

14. The system of claim 10, wherein the leak channel is positioned around a perimeter of the package base.

15. The system of claim 14, wherein the leak channel includes multiple sensors positioned within the leak channel around the package base.

16. The system of claim 10, wherein the package top plate includes one or more ports configured to circulate liquid through the package base.

17. A method of manufacturing liquid-cooled packages, the method comprising:
positioning one or more cooling components in a cooling chamber of a package base, wherein the package base includes the cooling chamber and a leak channel, wherein the leak channel is configured to catch and store liquid that has leaked out of the cooling chamber; and
coupling the package base to a package top plate.

18. The method of claim 17, further comprising positioning, in the leak channel of the package base, a sensor configured to detect the liquid that has leaked into the leak channel from the cooling chamber.

19. The method of claim 18, wherein a floor of the leak channel is configured to slope towards the sensor.

20. The method of claim 18, wherein the leak channel is positioned around a perimeter of the package base.
